(19) United States
(12) Patent Application Publication
(10) Pub. No.: US 2014/0145560 A1
(43) Pub. Date: May 29, 2014

(54) PIEZOELECTRIC VIBRATION MODULE

(71) Applicant: SAMSUNG ELECTRO-MECHANICS CO., LTD., Suwon (KR)

(72) Inventors: Dong Sun PARK, Suwon (KR); Yeon Ho Son, Suwon (KR); Jae Kyung Kim, Suwon (KR)

(73) Assignee: SAMSUNG ELECTRO-MECHANICS CO., LTD., Suwon (KR)

(21) Appl. No.: 13/828,836

(22) Filed: Mar. 14, 2013

(30) Foreign Application Priority Data
Nov. 29, 2012 (KR) 10-2012-0137144

(51) Int. Cl. H01L 41/09

(52) U.S. Cl. CPC H01L 41/0926
USPC 310/323.01

(57) ABSTRACT

Disclosed herein is a piezoelectric vibration module including: a vibration plate mounted with a piezoelectric device and including at least one first elastic member; a lower case spaced apart from the vibration plate by a predetermined interval, disposed to be in parallel with the vibration plate, and including at least one second elastic member protruded toward the vibration plate; and an upper case having a shape of a box and including at least one third elastic member protruded toward an inner portion of the box.

### CROSS REFERENCE TO RELATED APPLICATION

This application claims the benefit of Korean Patent Application No. 10-2012-0137144, filed on Nov. 29, 2012, entitled “Piezoelectric Vibration Module”, which is hereby incorporated by reference in its entirety into this application.

### BACKGROUND OF THE INVENTION

1. Technical Field

The present invention relates to a piezoelectric vibration module.

2. Description of the Related Art

Generally, in a portable electronic device such as a portable phone, an e-book terminal, a game machine, a portable multimedia player (PMP), or the like, a vibration function has been utilized for various uses.

Particularly, a vibration generating apparatus for generating the vibration has been mainly mounted in the portable electronic device to thereby be used as an alert function that is a soundless receiving signal.

In accordance with multi-functionalization of the portable electronic device, miniaturization, integration, and multi-functionalization of the vibration generating apparatus have been currently demanded.

Further, in accordance with the recent demand of users for simple usage of the portable electronic device, a touch type device performing an input by touching the electronic device has been generally adopted.

A concept of a currently generally used haptic device widely includes a concept of reflecting intuitive experience of an interface user and diversifying feedback for a touch, in addition to a concept of performing an input through a touch.

For example, Japanese Patent Laid-Open Publication No. 2000-278974 (Patent Document 1) has disclosed a piezoelectric linear motor using a piezoelectric device, which is an example of a haptic device. The piezoelectric linear motor includes a spring member disposed between the piezoelectric device and a base part.

The spring member is a compression coil spring capable of providing continuous elastic force so as to press the piezoelectric device from an actuator toward a cover. The elastic force of the spring member serves to closely adhere the piezoelectric device to the cover.

As well-known to those skilled in the art, a piezoelectric device made of a ceramic material provides driving force by vibration generated by a high frequency signal applied thereto. In this case, the vibrated piezoelectric device and the cover and/or the base part enclosing the piezoelectric device unnecessarily collide with each other, such that the piezoelectric device may be easily damaged.

However, the piezoelectric linear motor according to Patent Document 1 having the above-mentioned structure has a limitation that characteristics of the piezoelectric device that may be translated are not considered.

### PRIOR ART DOCUMENT

### Patent Document

Patent Document 1: Japanese Patent Laid-open Publication No. 2000-278974

### SUMMARY OF THE INVENTION

The present invention has been made in an effort to provide a piezoelectric vibration module capable of preventing or alleviating direct collision between internal components due to external impact and/or unexpected abnormal driving displacement of a piezoelectric device in the case in which the piezoelectric device is activated.

According to a preferred embodiment of the present invention, there is provided a piezoelectric vibration module including: a piezoelectric device repeatedly expansion and compression-deformed by external power applied thereto to generate vibration force; an upper case having an opened lower portion and forming an internal space so that the piezoelectric device is linearly vibrated; a lower case coupled to a lower portion of the upper case to cover the lower portion of the upper case; and a vibration plate including a flat plate mounted with the piezoelectric device and disposed in the upper and lower cases to thereby be driven in a vertical direction, wherein the vibration plate includes a first elastic member disposed on a flat surface of the plate.

The vibration plate may include: the flat plate; a pair of supports standing at the center of both sides of the plate in a vertical direction; and a weight body disposed between the pair of supports in order to increase the vibration force of the piezoelectric device.

The first elastic member may be formed of a plate shaped bent part formed by cutting a portion of the plate and protruded upwardly.

The first elastic member may be formed to be inclined upwardly from a central portion of the plate toward both end portions thereof so as not to have an effect on driving displacement of a weight body.

The first elastic member may be disposed at one end portion or both end portions of a flat surface of the plate except for a central portion of the plate.

The lower case may include a second elastic member formed of a plate shaped bent part formed by cutting a portion of the lower case and protruded upwardly.

The second elastic member may be formed to be inclined upwardly from a central portion of the lower case toward both end portions thereof so that the maximally driving-displaced piezoelectric device does not contact the lower case. In addition, the second elastic member may be disposed at one end portion or both end portions of the lower case except for a central portion of the lower case.

The upper case may include a third elastic member formed of a plate shaped bent part formed by cutting a portion of the upper case and protruded downwardly.

The third elastic member may be formed to be inclined downwardly from a central portion of the upper case toward both end portions thereof.

The piezoelectric vibration module may further include a first damper disposed between the weight body and the plate of the vibration plate so as not to be overlapped with the first elastic member and made of a flexible material.

The piezoelectric vibration module may further include a second damper disposed on an upper surface of the lower case so as not to be overlapped with the second elastic member and made of a flexible material.

The piezoelectric vibration module may further include a third damper disposed on a lower surface of the upper case so as not to be overlapped with the third elastic member and made of a flexible material.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view of a piezoelectric vibration module according to a preferred embodiment of the present invention when being viewed from the top;

FIG. 2 is an exploded perspective view of the piezoelectric vibration module shown in FIG. 1;

FIGS. 3A to 3C are views schematically showing a driving state of a vibration plate;

FIG. 4 is a cross-sectional view of a piezoelectric vibration module according to a first preferred embodiment of the present invention;

FIG. 5 is a perspective view of the piezoelectric vibration module from which an upper case is removed in FIG. 4;

FIG. 6 is a cross-sectional view of a piezoelectric vibration module according to a second preferred embodiment of the present invention;

FIG. 7 is a perspective view of the piezoelectric vibration module shown in FIG. 6 when being viewed from the bottom;

FIG. 8 is a cross-sectional view schematically showing a piezoelectric vibration module according to a third preferred embodiment of the present invention; and

FIG. 9 is a perspective view of the piezoelectric vibration module shown in FIG. 8 when being viewed from the top.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

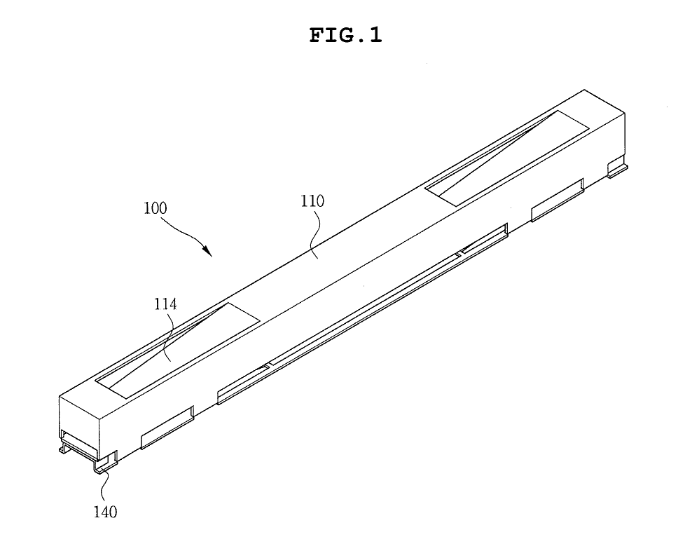

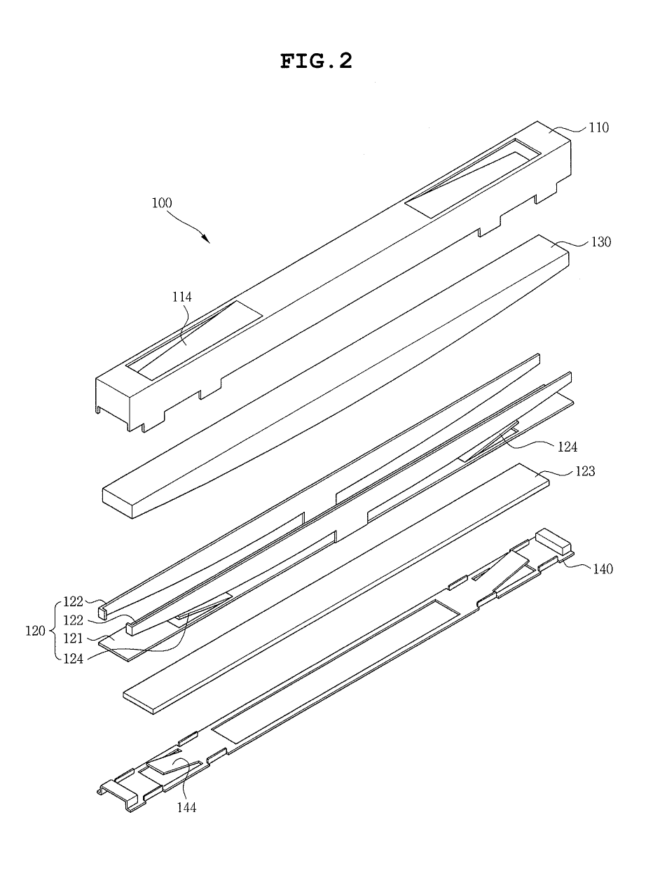

FIG. 1 is a perspective view of a piezoelectric vibration module according to a preferred embodiment of the present invention when being viewed from the top; and FIG. 2 is an exploded perspective view of the piezoelectric vibration module shown in FIG. 1.

As shown in FIGS. 1 and 2, the piezoelectric vibration module 100 according to the preferred embodiment of the present invention is configured to include an upper case 110, a vibration plate 120 including a piezoelectric device 123, a weight body 130, and a lower case 140. The piezoelectric vibration module 100 is used as a means for transferring vibration force to a touch screen panel (not shown).

The upper case 110 may have a box shape in which it has an opened one side and receive a driving body, more specifically, the vibration plate 120 mounted with the piezoelectric device 123 in an internal space thereof.

The vibration plate 120 may include a flat plate 121 and the piezoelectric device 123 and be repeatedly expansion and contraction-deformed integrally with the piezoelectric device 123 to transfer the vibration force of the piezoelectric device 123 to an external component by a bending operation. As shown, the plate 121 may include the piezoelectric device 123 mounted on a flat lower surface thereof and include the weight body 130 disposed on an upper surface thereof. The vibration plate 120 may include a printed circuit board (PCB) (not shown) applying power for driving the piezoelectric device 123.

Optionally, the vibration plate 120 may include a pair of supports 122 standing at both sides of the plate 212 in a vertical direction, in addition to the flat plate 121 as described above. The supports 122 are fixed to a central portion of the plate 121. The plate 121 and the support 122 may be formed of an integral signal component or be fixedly coupled to each other in various bonding schemes.

The vibration plate 120 is made of a metal material having elastic force, for example, SUS, so that it may be deformed integrally with the piezoelectric device 123 that is repeatedly expansion and compression-deformed by external power applied thereto. Further, in order to prevent a bending phenomenon that may be generated due to hardening of a bonding member in advance in the case in which the vibration plate 120 and the piezoelectric device 123 are coupled to each other in a bonding-coupling scheme, the vibration plate 120 may be made of invar, which is a material having a thermal expansion coefficient similar to that of the piezoelectric device.

As described above, the vibration plate 120 is made of the invar material having a thermal expansion coefficient similar to that of the piezoelectric device 123. Therefore, since thermal stress generated in the piezoelectric device 123 at the time of operation or thermal impact under a high temperature external environment is decreased, a piezoelectric deterioration phenomenon that electrical characteristics are deteriorated may be prevented.

The pair of supports 122 may be disposed to be in parallel with each other by, for example, a width of the plate 121 and have the weight body 130 disposed therebetween. The weight body 130, which is a medium increasing the vibration force as much as possible, is formed to be inclined upwardly from a central body thereof toward both end portions thereof in order to prevent a contact with the plate 121 of the vibration plate 120. Therefore, the support 122 are also formed to be inclined upwardly from a central portion thereof to both end portions thereof, similar to the shape of the weight body 130.

As described above, in the structure in which the vibration plate 120 includes the support 122, since the weight body 130 does not contact the plate 121, the piezoelectric device 123 may also be disposed on the plate 121.

For reference, the weight body 130 may be made of a metal material, preferably, a tungsten material having relatively high density in the same volume.

The lower case 140 is formed of a plate having a generally longitudinal flat shape as shown and is formed to have a size and a shape in which it may cover and close an opened lower surface of the upper case 110.

The upper case 110 and the lower case 140 may be coupled to each other in various schemes such as a caulking scheme, a welding scheme, a bonding scheme, or the like, well-known to those skilled in the art.

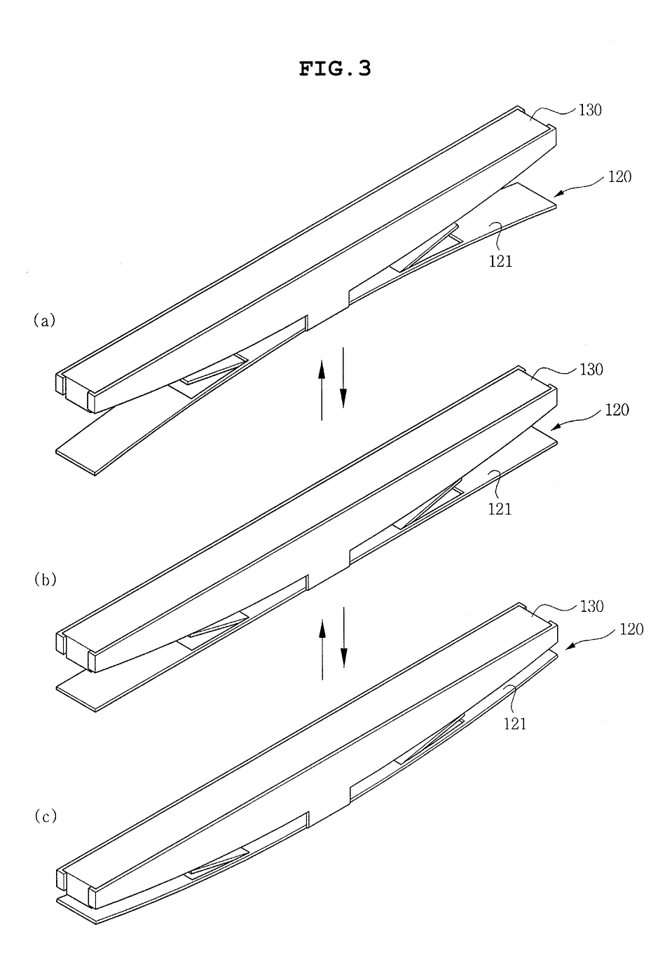

FIGS. 3A to 3C are views schematically showing a process of driving the vibration plate via the piezoelectric device generating the expansion and contraction deformation by the external power applied thereto. For reference, since the driving body (the vibration plate 120 and/or the weight body 130) viewed from the top is shown in FIGS. 3A to 3C, the piezoelectric device disposed under the vibration plate 120 is omitted in FIGS. 3A and 3C.

FIG. 3B shows only the driving body (the vibration plate 120 and/or the weight body 130) before the external power is applied.

FIG. 3A shows the vibration plate 120 in the case in which a length of the piezoelectric device is contracted at the time of applying the power. When the length of the piezoelectric device is contracted, the plate 121 is bent upwardly and driven.

During the contraction of the piezoelectric device, the weight body 130 and the upper case will be disposed to be significantly close to each other. When large driving displacement that is out of an allowable range is generated in the vibration plate 120, the weight body 130 and the upper case 110 (See FIG. 2) will collide with each other. When impact force due to the collision is transferred to the piezoelectric, it has a negative effect on the piezoelectric device, such that the piezoelectric device may be damaged. Therefore, according to the preferred embodiment of the present invention, in spite of the driving displacement of the vibration plate 120 that is out of the allowable range, an elastic member capable of alleviating the impact force is interposed between the weight body 130 and the upper case 110, which will be described below in detail.

FIG. 3C shows the vibration plate 120 in the case in which a length of the piezoelectric device is expanded at the time of applying the power. When the length of the piezoelectric device is expanded, since the plate 121 has a relatively small deformation rate and is fixed to both end portions of the lower case 140 (See FIG. 2), the vibration plate 120 is bent downwardly and driven.

During the expansion of the piezoelectric device, the vibration plate 120 and the weight body 130, and the vibration plate 120 and the lower case will be disposed to be close to each other. When large driving displacement that is out of an allowable range is generated in the vibration plate 120, the plate 121 and the lower case 140 (See FIG. 2) and/or the weight body 130 will collide with each other. When impact force due to the collision is transferred to the piezoelectric, it has a negative effect on the piezoelectric device, such that the piezoelectric device may be damaged. Therefore, according to the preferred embodiment of the present invention, in spite of the driving displacement of the vibration plate 120 that is out of the allowable range, an elastic member capable of alleviating the impact force is interposed between the weight body 130 and the plate 121 of the vibration plate 120 and the plate 121 and the lower case 140, which will be described below in detail.

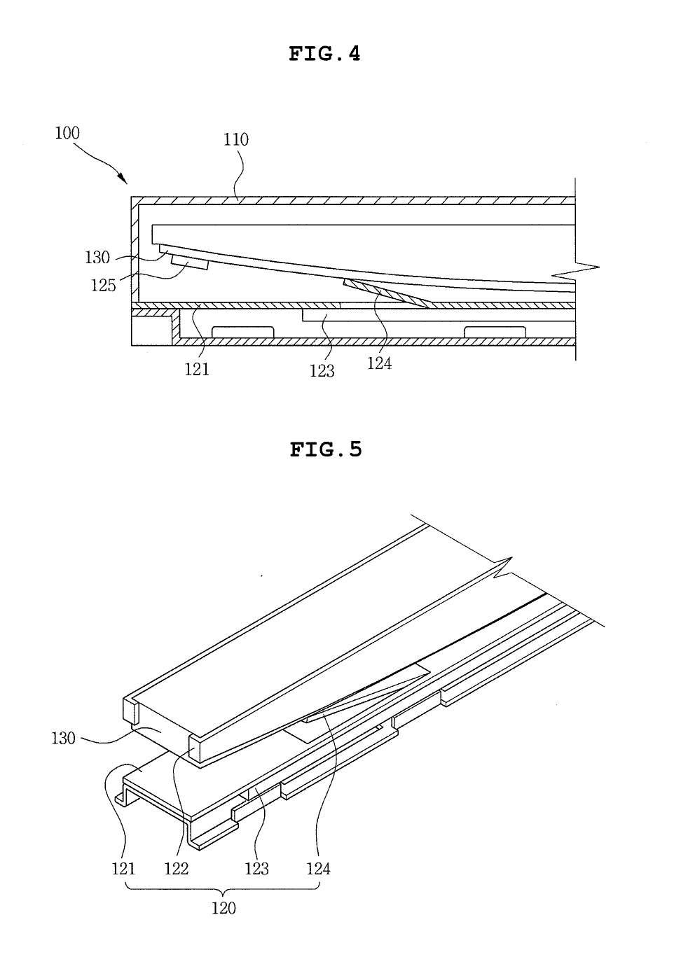

FIG. 4 is a cross-sectional view of a piezoelectric vibration module according to a first preferred embodiment of the present invention; and FIG. 5 is a perspective view of the piezoelectric vibration module from which an upper case is removed in FIG. 4.

Referring to FIGS. 4 and 5, the piezoelectric vibration module 100 according to the first preferred embodiment of the present invention includes a first elastic member 124 provided on the vibration plate 120 on which the weight body 130 is mounted. More specifically, the first elastic member 124 is provided on the plate 121 of the vibration plate 120.

As shown in FIGS. 4 and 5, the first elastic member 124 may be formed of a plate shaped bent part formed by cutting a portion of the plate 121, but is not limited thereto. That is, a well-known elastic spring may also be used on the plate 121.

The first elastic member 124, which is formed by bending the plate 121 as described above, is formed integrally with the plate 121 and is made of the same material as that of the plate 121, such that the first elastic member 124 has reliable durability without being separated or disassembled from the plate 121.

The first elastic member 124 according to the preferred embodiment of the present invention is provided on an upper surface of the plate 121 so as to prevent collision between the plate 121 and the weight body 130. Particularly, the first elastic member 124 is formed to be inclined upwardly from a central portion of the plate 121 toward both end portions thereof so as not to have an effect on driving displacement of the weight body 130.

One end portion of the first elastic member 124 may be disposed to contact the weight body 130 or the support 122 as shown in FIGS. 4 and 5 or to be spaced apart from the weight body 130 or the support 122 by a predetermined interval. In the case in which the weight body 130 and the plate 121 unnecessarily collide with each other as shown in FIG. 3C, the weight body 130 first contacts the first elastic member 124, and the first elastic member 124 has a leaf spring structure by a shape of the bent part or is made of a metal material having elastic force to decrease a downward movement distance of the weight body 130, thereby making it possible to apply impact to the plate 121 as small as possible.

The first elastic member 124 is formed by cutting a portion of the plate 121 as shown in FIGS. 4 and 5. Therefore, according to the preferred embodiment of the present invention, a separate elastic component is not required, thereby making it possible to decrease a material cost and significantly decrease the number of workers according to the mounting. Therefore, slimness and lightness of the piezoelectric vibration module may be accomplished.

In addition, the first elastic member 124 may be disposed at one end portion or both end portions of the plate 121.

Further, the piezoelectric vibration module according to the first preferred embodiment of the present invention may further include a first damper 125 disposed at both end portions of a lower surface of the weight body 130. The first damper 125 is not limited thereto, but may also be provided on an upper surface of the plate 121. The first damper 125 is to alleviate impact force between the plate 121 and the weight body 130, similar to the first elastic member 124. To this end, the first damper 125 may be made of various materials including a flexible material such as rubber.

It is preferable that the first damper 125 is disposed so as not to be overlapped with the first elastic member 124.

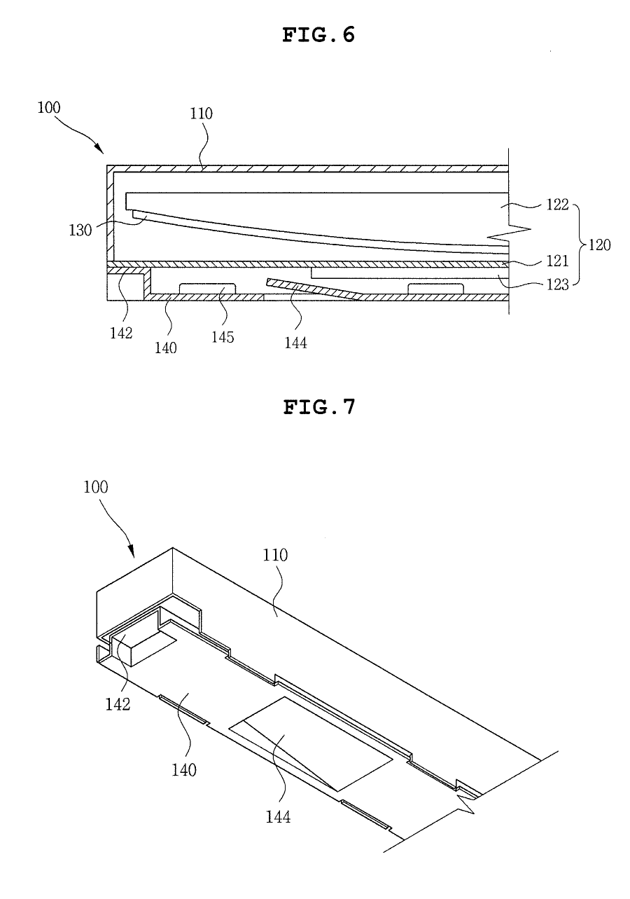

FIG. 6 is a cross-sectional view of a piezoelectric vibration module according to a second preferred embodiment of the present invention; and FIG. 7 is a perspective view of the piezoelectric vibration module shown in FIG. 6 when being viewed from the bottom.

Referring to FIGS. 6 and 7, the piezoelectric vibration module 100 according to the second preferred embodiment of the present invention includes a second elastic member 144 provided on the lower case 140. More specifically, the second elastic member 144 is provided on the lower case 140.

As shown in FIGS. 6 and 7, the second elastic member 144 may be formed of a plate shaped bent part formed by cutting a portion of the lower case 140, but is not limited thereto. That is, a well-known elastic spring may also be used on the lower case 140.

The vibration plate 120 is spaced apart from the lower case 140 by a predetermined interval so as to be in parallel with each other, as shown in FIGS. 6 and 7. Preferably, the lower case 140 includes a coupling end 142 protruded upwardly at both end portions thereof, and both end portions of the flat plate 121 is seated on and fixed to the coupling end 142 of the lower case 140. In other words, the piezoelectric vibration module 100 is configured to allow the vibration plate 120 and the lower case 140 to be spaced apart from each other by the coupling end 142 of the lower case 140 to form a space therebetween.

Unlike this, the plate 121 may be seated on and fixed to both end portions of the lower case 140 by a step part (not shown) stepped downwardly at both end portions thereof.

As described above, the second elastic member 144 according to the preferred embodiment of the present invention is provided on an upper surface of the vibration plate 120, particularly, the lower case 140 so as to prevent collision between the plate 121 and the lower case 140. Particularly, the second elastic member 144 is formed to be inclined upwardly from a central portion of the lower case 140 toward both end portions thereof so as not to have an effect on driving displacement of the vibration plate 120.

One end portion of the second elastic member 144 may be disposed to contact the plate 121 as shown in FIGS. 6 and 7 or to be spaced apart from the plate 121 by a predetermined interval. In the case in which the plate 121 of the vibration plate and the lower case 140 contacts each other due to the expansion of the piezoelectric device 123 as shown in FIG. 3C, the plate 121 first contacts the second elastic member 144, and the second elastic member 144 has a leaf spring structure by a shape of the bent part as shown in FIGS. 6 and 7 or is made of a metal material having elastic force to limit downward movement of the vibration plate 120, thereby making it possible to minimize impact applied to the piezoelectric device 123.

The second elastic member 144 may be formed by cutting a portion of the lower case 140 and be disposed at one end portion or the both end portions of the lower case 140.

Further, the piezoelectric vibration module according to the second preferred embodiment of the present invention may further include a second damper 145 disposed at both end portions of an upper surface of the lower case 140. The second damper 145 is to prevent a contact between the plate 121 and the lower case 140 and alleviate impact force therebetween, similar to the first damper 144. To this end, the second damper 145 may be made of various materials including a flexible material such as rubber.

It is preferable that the second damper 145 is disposed so as not to be overlapped with the second elastic member 144.

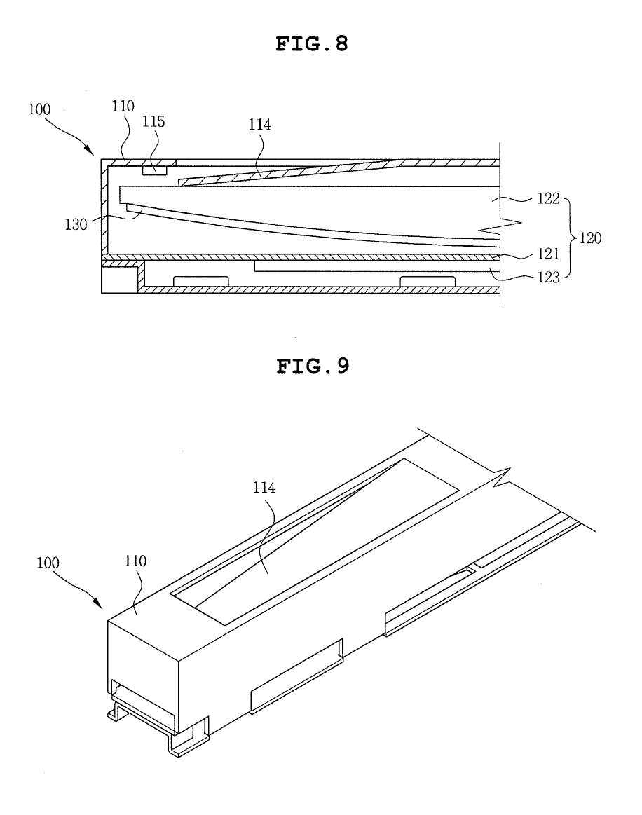

FIGS. 8 and 9 are views schematically showing a piezoelectric vibration module according to a third preferred embodiment of the present invention. Hereinafter, a description of components that are similar to or the same as those of the piezoelectric vibration module according to the first preferred embodiment of the present invention and the piezoelectric vibration module according to the second preferred embodiment of the present invention described above will be omitted.

The piezoelectric vibration module 100 according to the third preferred embodiment of the present invention includes a third elastic member 114 formed by cutting a portion of the upper case 110. The third elastic member 114 is formed to be inclined downwardly, thereby making it possible to prevent the collision between the weight body 130 and the upper case 110 due to the expansion and contraction deformation of the piezoelectric device 123 as shown in FIG. 3A.

One end portion of the third elastic member 114 may be disposed to contact the weight body 130 or the support 122 or to be spaced apart from the weight body 130 or the support 122 by a predetermined interval. In the case in which the weight body 130 and the upper case 110 collide with each other as shown in FIG. 3A, the weight body 130 first contacts the third elastic member 114, and the third elastic member 114 has a leaf spring structure by a shape of the bent part as shown in FIGS. 8 and 9 or is made of a metal material having elastic force to limit upward movement of the weight body 130, such that impact between the weight body 130 and the upper case 110 is minimized, thereby making it possible to ensure drop reliability.

Preferably, the third elastic member 114 may be formed to be inclined downwardly from a central portion of the upper case 110 toward both end portions thereof so as not to have an effect on the driving displacement of the weight body 130 and may be disposed at one end portion or both end portions of the upper case 110.

Further, the piezoelectric vibration module according to the third preferred embodiment of the present invention may further include a third damper 115 disposed at both end portions of a lower surface of the upper case 110. The third damper 115 may be made of various materials including a flexible material such as rubber to alleviate impact force.

It is preferable that the third damper 115 is disposed so as not to be overlapped with the third elastic member 114.

As set forth above, according to the preferred embodiment of the present invention, at least one elastic member is provided so as to alleviate impact between the driving body that is driving-displaced due expansion and contraction of the piezoelectric device and other components.

Specially, the respective elastic members according to the preferred embodiment of the present invention are formed to correspond to the driving displacement of the driving body formed of the vibration plate mounted with the weight body and/or the piezoelectric device to have an effect as small as possible on the driving displacement, thereby making it possible to ensure an intuitive experience of haptic via generation of the vibration through a touch.

Particularly, the respective elastic members according to the preferred embodiment of the present invention are formed of the plate shaped bent part formed by cutting a portion of the component, thereby making it possible to accomplish slimness and lightness of the piezoelectric vibration module.

The piezoelectric vibration module according to the preferred embodiment of the present invention may be manufactured by simply cutting a portion of the flat surface without performing a separate design change in the piezoelectric vibration module according to the related art.

Further, the piezoelectric vibration module according to the preferred embodiment of the present invention may further include the damper made of a flexible material, in addition to the elastic member made of a rigid material capable of enduring drop impact.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A piezoelectric vibration module comprising:
a piezoelectric device repeatedly expansion and compression-deformed by external power applied thereto to generate vibration force;
an upper case having an opened lower portion and forming an internal space so that the piezoelectric device is linearly vibrated;
a lower case coupled to a lower portion of the upper case to cover the lower portion of the upper case; and
a vibration plate including a flat plate mounted with the piezoelectric device and disposed in the upper and lower cases to thereby be driven in a vertical direction,
wherein the vibration plate includes a first elastic member disposed on a flat surface of the plate.

2. The piezoelectric vibration module as set forth in claim 1, wherein the first elastic member is formed of a plate shaped bent part formed by cutting a portion of the plate and protruded upwardly.

3. The piezoelectric vibration module as set forth in claim 1, wherein the first elastic member is formed to be inclined upwardly from a central portion of the plate toward both end portions thereof.

4. The piezoelectric vibration module as set forth in claim 1, wherein the first elastic member is disposed at one end portion or both end portions of a flat surface of the plate.

5. The piezoelectric vibration module as set forth in claim 1, wherein the vibration plate includes:
the flat plate;
a pair of supports standing at the center of both sides of the plate in a vertical direction; and
a weight body disposed between the pair of supports in order to increase the vibration force of the piezoelectric device.

6. The piezoelectric vibration module as set forth in claim 1, wherein the lower case includes a second elastic member formed of a plate shaped bent part formed by cutting a portion of the lower case and protruded upwardly.

7. The piezoelectric vibration module as set forth in claim 6, wherein the second elastic member is formed to be inclined upwardly from a central portion of the lower case toward both end portions thereof.

8. The piezoelectric vibration module as set forth in claim 1, wherein the upper case includes a third elastic member formed of a plate shaped bent part formed by cutting a portion of the upper case and protruded downwardly.

9. The piezoelectric vibration module as set forth in claim 8, wherein the third elastic member is formed to be inclined downwardly from a central portion of the upper case toward both end portions thereof.

10. The piezoelectric vibration module as set forth in claim 5, further comprising a first damper disposed between the weight body and the plate of the vibration plate.

11. The piezoelectric vibration module as set forth in claim 1, further comprising a second damper disposed on an upper surface of the lower case.

12. The piezoelectric vibration module as set forth in claim 1, further comprising a third damper disposed on a lower surface of the upper case.
